(19) United States
(12) Patent Application Publication
(10) Pub. No.: US 2009/0108444 A1
(43) Pub. Date: Apr. 30, 2009

(54) CHIP PACKAGE STRUCTURE AND ITS FABRICATION METHOD

(75) Inventor: BILL CHUANG, YILAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: TAIWAN SOLUTIONS SYSTEMS CORP., HSINCHU CITY (TW)

(21) Appl. No.: 11/931,159

(22) Filed: Oct. 31, 2007

(51) Int. Cl. H01L 23/49; H01L 21/58

(52) U.S. Cl. 257/737; 438/124; 257/E23.024; 257/E21.505

(57) ABSTRACT

A chip package structure and its fabrication method are disclosed. Method of electrically connecting a chip with plural different metal layers is utilized to replace the conventional method of connecting identical metal layer merely. Besides, the method of a protective layer directly set on the metal layer to cover the chip and the conductive connecting structure is different from the general method of coating the solder mask on the metal layer. Moreover, a carrier utilized for support makes lighter and thinner substrate be fabricated. The fabrication method is utilized to manufacture by using the fabrication process of present package manufacturing. No additional equipments and fabrication processes are needed so that the PCB production flow may be simplified to reduce the package cost.

### BACKGROUND OF THE INVENTION

1. Field of the Invention

The present invention relates to a chip package technology. More particularly, the present invention relates to a chip package structure and a method for fabricating thin-type reversible substrate.

2. Description of the Prior Art

Along with the rapid progress of the computer and internet communication, the semiconductor products need to be multi-functional, portable, light, thin and small-sized to satisfy the customers' demand. Therefore, the industry of chip package has to develop towards the high accurate processes to comply with the requirements of high-power, high-density, lightness, thinness, compactness and mini-size. In order to fabricate thinner and lighter substrate, the package fabricating process must be complicated to meet the product of requirement but the complicated process may lead to higher damage rate.

### SUMMARY OF THE INVENTION

According to the issue mentioned previously, the present invention provides a chip package structure and its fabrication method to improve the mentioned issue.

One object of the present invention is to provide a chip package structure and its fabrication method with a protective layer directly set on a metal layer and covered the chips and the conductive connecting structures, so as to not only promote the reliability but also reduce the production cost.

Another object of the present invention is to provide a chip package structure and its fabrication method which utilize a carrier for support to make the package fabrication method easier than the conventional method. Otherwise, the users may fabricate the structure of the present invention based on the present flow so that the fabrication yield may be increased.

Another object of the present invention is to provide a chip package structure and its fabrication method which utilize the carrier for support so that the thinner and lighter substrate may be fabricated to meet the present requirement of the semiconductor technology.

Another object of the present invention is to provide a chip package structure and its fabrication method which utilize a carrier for support. As the carrier is removed, the remainder substrate structure may be fabricated as a reversible substrate so as to electrically connect to other electrical devices conveniently.

Further another object of the present invention is to provide a chip package structure and its fabrication method that may be implemented by existing fabrication process of the package manufacturing. Hence, the additional equipments or fabrication processes are unneeded so as to lower the package cost.

To achieve the objects mentioned above, one embodiment of the present invention is to provide a method for fabricating a chip package structure, which includes following steps: providing a carrier having an insulating layer set thereon and a conductive layer set on a surface of the insulating layer; removing a portion of the conductive layer and a portion of the insulating layer to expose a portion of the carrier; forming a first metal layer on the conductive layer, the insulating layer and an exposed portion of the carrier; removing a portion of the first metal layer and a portion of the conductive layer to expose a portion of the insulating layer; forming a second metal layer on a portion of the first metal layer; arranging at least a chip on at least a portion of the first metal layer; electrically connecting the chip to at least any one of the first metal layer and the second metal layer; forming a protective layer to cover the chip; and removing the carrier.

According to another embodiment of the present invention is to provide a chip package structure, which includes: an insulating layer; a conductive layer arranged on a portion of the insulating layer; a first metal layer arranged on a portion of the conductive layer and part of an exposed portion of the insulating layer; a second metal layer arranged on a portion of the first metal layer; at least a chip arranged on at least any one of the first metal layer and the second metal layer; a conductive connecting structure electrically connected the chip to at least any one of the first metal layer and the second metal layer; and a protective layer directly covered an exposed portion of the first metal layer, the second metal layer, the chip, the conductive connecting structure, an exposed portion of the conductive layer and the exposed portion of the insulating layer.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

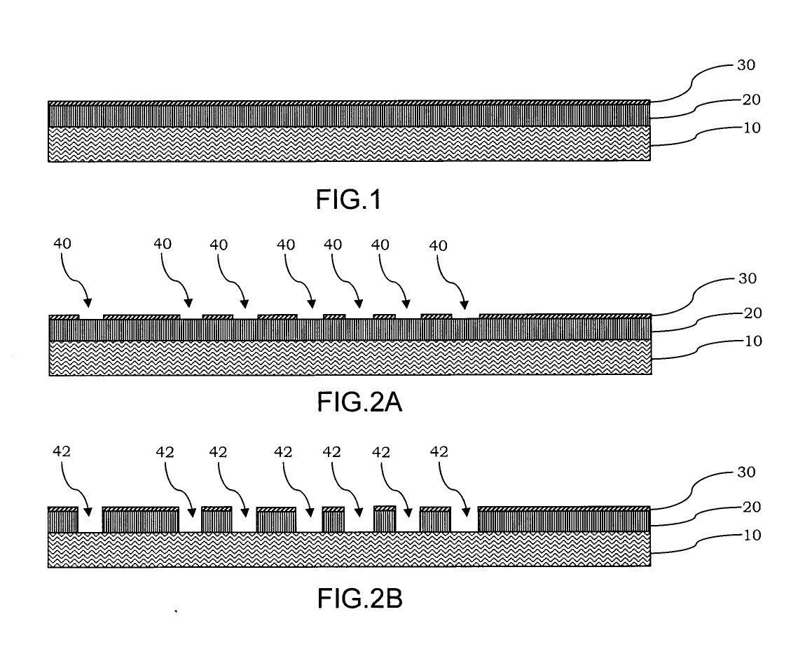

From FIG. 1 to FIG. 12 are cross-section view schematic diagrams of the method for fabricating the chip package structure in accordance with one embodiment of the present invention.

### DETAILED DESCRIPTION OF THE INVENTION

The detailed explanation of the present invention is described as following. The described preferred embodiments are presented for purposes of illustrations and description, and they are not intended to limit the scope of the present invention.

Referring to FIG. 1, First, a carrier 10 has an insulating layer 20 set thereon and a conductive layer 30 arranged on the insulating layer 20. In one embodiment, the insulating layer 20 and the conductive layer 30 may be one-piece formed commodity, such as the resin coated copper foil (RCC). In another embodiment, the carrier 10 provided with the insulating layer 20 and the conductive layer 30 may be formed in three steps. Foremost, the insulating layer 20, such as a glass fiber prepreg, is set on the carrier 10, such as a metal, a glass, a ceramics, and a polymeric carrier, by using conventional suitable method of pasting, printing, spray coating, spin coating or laminating. Next, the conductive layer 30, for instance a gold foil, is formed on the insulating layer 20 by using the pasting, printing, sputtering, laminating, electroless plating or electroplating. In one embodiment, the surface of the conductive layer 30 may also be processed with conventional rough methods of brown-oxide procedure, black-oxide procedure, microetch procedure, scrubbing procedure, or sand blasting procedure.

Next, refer to FIG. 2A, a portion of the conductive layer 30 is removed to form plural first patterned fillisters 40 as a mask for removing insulating layer 20. In one embodiment, the step of removing the conductive layer 30 may be undertaken with the conventional lithography procedure, photo-etching procedure or laser cutting eneraving procedure. After, a portion of the insulating layer 20 may be removed at part of those first patterned fillisters 40 to form plural second patterned fillisters 42 to expose a portion of the carrier 10, wherein the insulating layer 20 may be removed by utilizing hole drilling procedure, depth control procedure, laser procedure or plasma method, as shown in FIG. 2B.

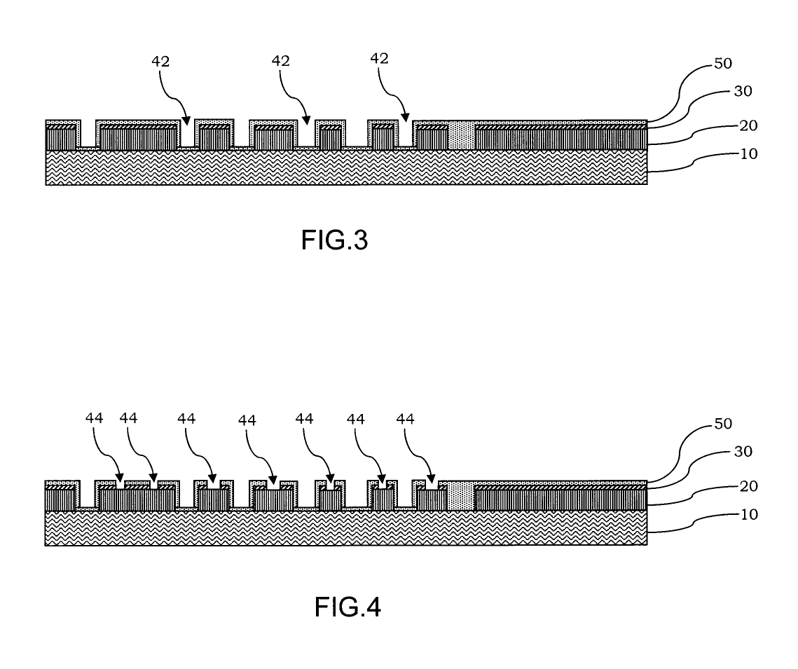

Next, a first metal layer 50 is formed on the conductive layer 30, the insulating layer 20 and an exposed portion of the carrier 10, as shown in FIG. 3. In one embodiment, the first metal layer 50 is made of copper material by sputtering, evaporating, electroless plating or electroplating for conducting each layer. Besides, before the first metal layer 50 is formed, electroless copper (plate through hole, PTH) and/or black-hole etc. procedures may be utilized to increase the absorbability between the first metal layer 50 and the insulating layer 20. Furthermore, the surface of the first metal layer 50 may be processed with the conventional rough methods of brown-oxide, black-oxide, microetch, scrubbing, and sand blasting. In another embodiment, those second pattern fillisters 42 further may be filled with the first metal layer 50.

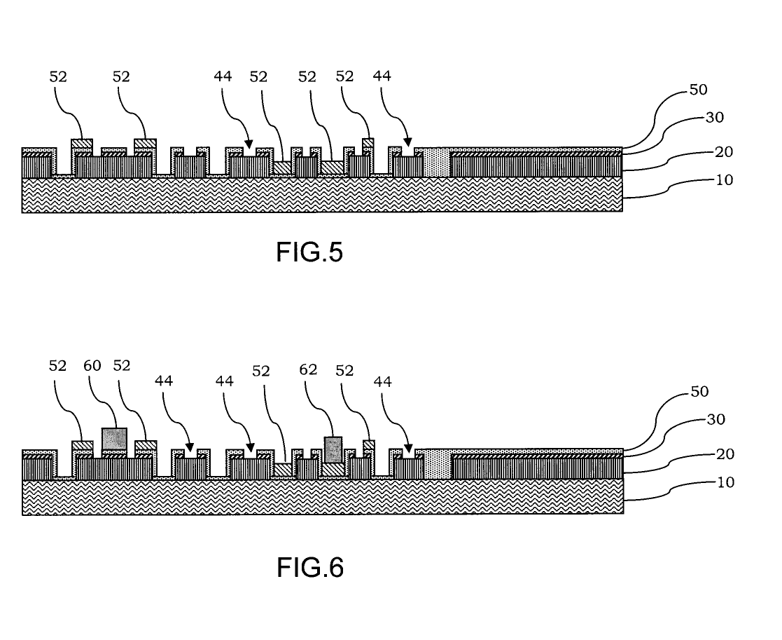

Continually, refer to FIG. 4, a portion of the first metal layer 50 and part of the conductive layer 30 may be removed to expose a portion of the insulating layer 20 to form a plurality of third patterned fillisters 44. In one embodiment, the methods of removing the first metal layer 50 and the conductive layer 30 may be lithography procedure, photo-etching procedure or laser cutting eneraving procedure. Those patterned fillisters are used for external layout, but it is understood that those patterned fillisters in the present invention may not be limited for external layout. After, such as shown in FIG. 5, a second metal layer 52 is formed on a portion of the first metal layer 50 as electrically connecting contact. In one embodiment, the second metal layer 52 is fabricated with printing procedure, sputtering procedure, evaporating procedure, electroless plating procedure or electroplating procedure. Next, the second metal layer 52 is made of gold, silver, tin, aluminum, electroless nickel and immersion gold, immersion silver, immersion tin, electroless nickel and immersion gold, electroless silver plating and electroless tin plating. Moreover, the surface of the second metal layer 52 may be fabricated with the conventional rough methods of brown-oxide procedure, black-oxide procedure, microetch procedure, scrubbing procedure, and sand blasting procedure.

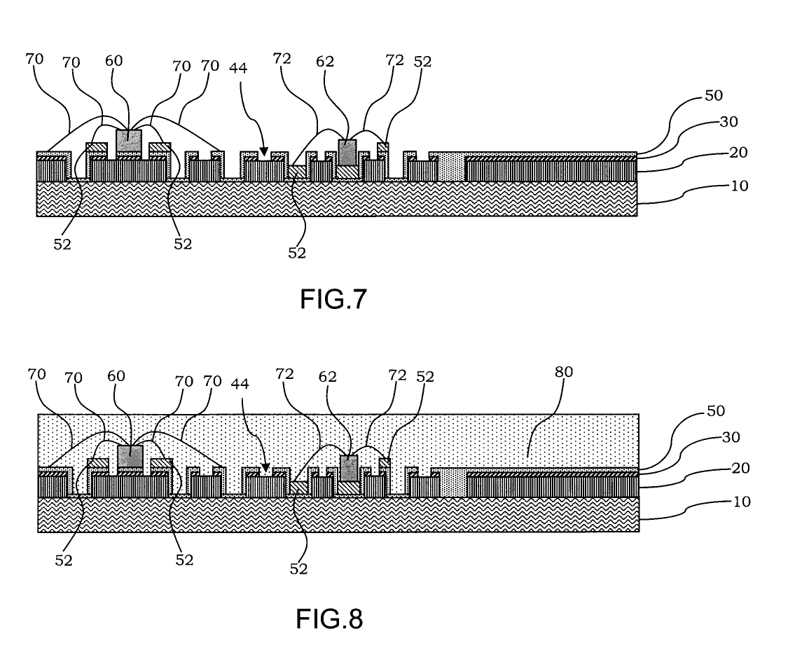

Further, please refer to FIG. 6, a suitable and conventional way, such as a die bonding process, is utilized to arrange one or plural chips on at least any one of the first metal layer 50 and the second metal layer 52, wherein those chips may have different functions, such as chip 60 and chip 62, and the active surface of those chips 60, 62 faces upward. In one embodiment, those chip 60 and chip 62 further comprise a conductive connecting structure set thereon, for instance, the conductive connecting structure may be bonding pad (not shown in figure). Continually, refer to FIG. 7, in one embodiment, the conductive connecting structure, such as bonding wire 70 and bonding wire 72, are electrically connecting these chip 60, 62 with at least any one of the first metal layer 50 and the second metal layer 52. Ac cording to the above mentioned description, those chips 60, 62 with identical function may electrically connect to different first metal layer 50 and the second metal layer 52. Moreover, different chip 60 and chip 62 may electrically connect to different first metal layer 50 and second metal layer 52 to meet the needs of different package designs. There after, as shown in FIG. 8, a molding procedure is sequentially undertaken. A protective layer 80 is fabricated to cover the chip 60, 62, bonding wire 70, 72, the first metal layer 50, the second metal layer 52, an exposed portion of the conductive layer 30 and the insulating layer 20. Accordingly, one feature of the present invention is no photosensitive protective layer, such as a solder mask, set on the first metal layer 50, the second metal layer 52 and the conductive layer 30. The protective layer 80 directly touches the chip 60, 62, bonding wire 70, 72, the first metal layer 50, the second metal layer 52, the conductive layer 30, and the insulating layer 20. Such structure may be fabricated to overcome the efficiency issue caused by the photosensitive protective layer to not only improve the reliability but also simplify the procedure so as to lower the production cost.

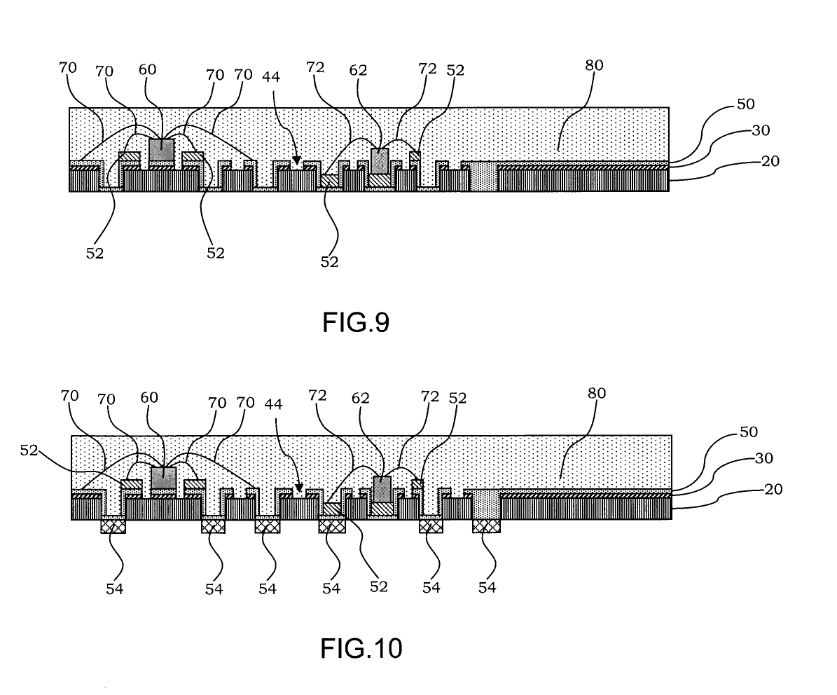

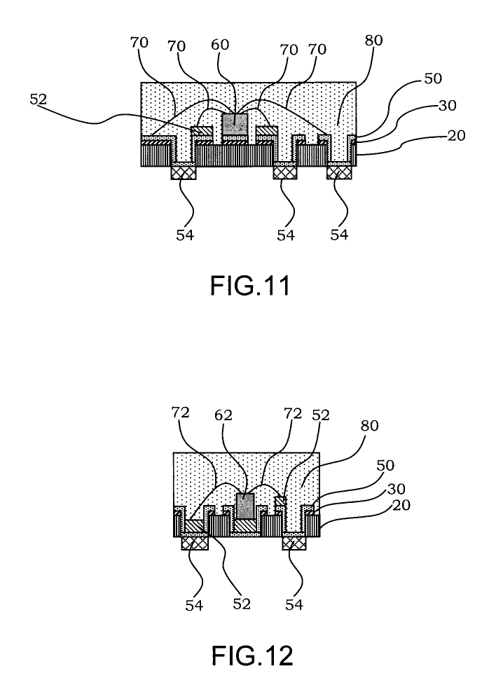

Next, as shown in FIG. 9 and FIG. 10, a suitable method is utilized to remove the carrier 10 and expose part of the first metal layer 50. Subsequently, a conductive connecting structure 54, such as a bump, is set on an exposed portion of the first metal layer 50 by using the surface mount technology (SMT) or electroplating technology so as to electrically connect with other electrical devices. Further, a plurality of the chip package structures is formed by dicing in accordance with a unit of each chip, such as shown in FIG. 11 and FIG. 12. In one embodiment, the chip package structure fabricated according to the above-mentioned method of present invention may include a conductive layer arranged on an insulating layer, and the first metal layer arranged on part of the conductive layer and part of an exposed portion of the insulating layer. Moreover, a second metal layer is set on part of the first metal layer and at least a chip is set on at least any one of the first metal layer and the second metal layer. Continually, a conductive connecting structure, such as the bonding wire, etc., is arranged on at least any one of the first metal layer and the second metal layer. Finally, a protective layer is formed to cover the first metal layer, the second metal layer and an exposed portion of the conductive layer and the insulating layer.

To sum up the foregoing descriptions, the present invention provides a chip package structure and its fabrication method. A carrier is utilized for support so as to fabricate ultra thin substrate, and further the revisable substrate may be fabricated. Moreover, owing to the support of the carrier the process may be simplified. Further, the fabrication method of the invention may be processed by present PCB manufacturing process and additional equipments or fabricating processes are unneeded so as to lower the production cost of the substrate. Otherwise, the present structure differs from the conventional structure which is coated with the solder mask layer. The protective layer is formed to directly contact and cover the metal layer, the conductive layer, the insulating layer, those chips and the conductive connecting structure so as to not only improve the reliability but also lower the cost of the solder mask. The package manufacturers which fabricate the substrate of the invention don't need to purchase additional equipments or add other fabrication process. Hence, the thickness of the package structure may be reduced and the requirement of thin light-weight electrical device may be met to lower the overall package cost.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A method for fabricating a chip package structure, comprising:
providing a carrier having an insulating layer set thereon and a conductive layer set on said insulating layer;
removing a portion of said conductive layer and a portion of said insulating layer to expose a portion of said carrier;
forming a first metal layer on said conductive layer, said insulating layer and an exposed portion of said carrier;
removing a portion of said first metal layer and a portion of said conductive layer to expose a portion of said insulating layer;
forming a second metal layer on a portion of said first metal layer;
arranging at least a chip on at least any one of a portion of said first metal layer and a portion of said second metal layer;
electrically connecting said chip to at least any one of said first metal layer and said second metal layer;
forming a protective layer to cover said chip; and
removing said carrier.

2. The method for fabricating the chip package structure according to claim 1, wherein said insulating layer is formed by pasting, laminating, printing, spray coating or spin coating.

3. The method for fabricating the chip package structure according to claim 1, wherein said conductive layer is formed by pasting, laminating, printing, spray coating, spin coating, evaporating, sputtering, electroless plating or electroplating.

4. The method for fabricating the chip package structure according to claim 1, further comprising a procedure of brown-oxide, black-oxide, microetch, scrubbing, or sand blasting processed on said conductive layer.

5. The method for fabricating the chip package structure according to claim 1, wherein said first metal layer is formed by sputtering, evaporating, electroless plating or electroplating.

6. The method for fabricating the chip package structure according to claim 1, further comprising a procedure of brown-oxide, black-oxide, microetch, scrubbing, or sand blasting processed on said first metal layer.

7. The method for fabricating the chip package structure according to claim 1, wherein said second metal layer is formed by sputtering, evaporating, electroless plating or electroplating.

8. The method for fabricating the chip package structure according to claim 1, further comprising a procedure of brown-oxide, black-oxide, brown-oxide, microetch, scrubbing or sand blasting processed on said second metal layer.

9. The method for fabricating the chip package structure according to claim 1, wherein the step of removing a portion of said conductive layer is fabricated by utilizing the methods of lithography, photo-etching or laser cutting eneraving.

10. The method for fabricating the chip package structure according to claim 1, wherein said exposed portion of said carrier is formed by using hole drilling, depth control, laser or plasma method.

11. The method for fabricating the chip package structure according to claim 1, wherein the step of removing a portion of said first metal layer and a portion of said conductive layer to expose a portion of said insulating layer is fabricated with the methods of lithography, photo-etching or laser cutting eneraving.

12. The method for fabricating the chip package structure according to claim 1, further comprising forming a plurality of said chip package structures by dicing in accordance with a unit of each said chip.

13. A chip package structure, comprising:
an insulating layer;
a conductive layer arranged on a portion of said insulating layer;
a first metal layer arranged on a portion of said conductive layer and part of an exposed portion of said insulating layer;
a second metal layer arranged on a portion of said first metal layer;
at least a chip arranged on at least any one of said first metal layer and said second metal layer;
a conductive connecting structure electrically connected said chip to at least any one of said first metal layer and said second metal layer; and
a protective layer formed to cover an exposed portion of said first metal layer, said second metal layer, said chip, said conductive connecting structure, an exposed portion of said conductive layer and said exposed portion of said insulating layer.

14. The chip package structure according to claim 13, wherein said conductive connecting structure comprises at least a bonding wire or at least a connecting pad.

15. The chip package structure according to claim 13, wherein said insulating layer is made of glass fiber prepreg or polymeric materials

16. The chip package structure according to claim 13, wherein said first metal layer is made of copper material.

17. The chip package structure according to claim 13, wherein said second metal layer is made of gold, silver, tin, aluminum, electroless nickel and immersion gold, immersion silver, immersion tin material, electroless nickel and immersion gold, electroless silver plating and electroless tin plating.

18. The chip package structure according to claim 13, wherein said insulating layer is the commercial product of resin coated copper foil.

19. The chip package structure according to claim 13, wherein said conductive layer is the commercial product of resin coated copper foil.

20. The chip package structure according to claim 13, wherein said protective layer is made of a molding component.

21. The chip package structure according to claim 13, further comprising a carrier arranged below said insulating layer to expose a portion of said carrier.

22. The chip package structure according to claim 21, wherein said first metal layer is arranged on said conductive layer, said carrier and said exposed portion of said insulating layer.

23. The chip package structure according to claim 21, further comprising a bump set on an exposed portion of said first metal layer after removing said carrier.

24. The chip package structure according to claim 23, wherein said bump is made of tin, tin-lead, silver, gold, and nickel-gold materials.
